(19) United States
(12) Patent Application Publication
(10) Pub. No.: US 2007/0069309 A1
(43) Pub. Date: Mar. 29, 2007

(54) Buried well for semiconductor devices

(76) Inventors: Richard Lindsay, Fishkill, NY (US); Phung T. Nguyen, Pleasant Valley, NY (US); Jeong-Hwan Yang, Fishkill, NY (US)

Correspondence Address: SLATER & MATSIL LLP, 17950 PRESTON ROAD, SUITE 1000, DALLAS, TX, 75252, US

(21) Appl. No.: 11/235,575

(22) Filed: Sep. 26, 2005

(51) Int. Cl. H01L 29/76

(52) U.S. Cl. 257/408

(57) ABSTRACT

A substrate having a buried well is provided. The substrate may be formed by implanting ions in a surface well of a first substrate and subsequently forming a semiconductor layer, such as an epitaxial layer, over the surface well. In this manner, the surface well becomes a buried well having a semiconductor layer that is substantially undoped formed thereon. In an embodiment, a transistor is formed on the substrate. Because the epitaxial layer is substantially undoped, the transistor may be formed such that the junction capacitance between the source/drain regions and the underlying region is reduced. If desired, the epitaxial layer, or a portion thereof, may be doped to decrease the resistance between the channel region and the well contact.

### TECHNICAL FIELD

The present invention relates generally to semiconductor devices and, more particularly, to buried wells for semiconductor devices.

### BACKGROUND

Semiconductor devices such as complementary metal-oxide-semiconductor (CMOS) transistors typically include a gate electrode and a gate dielectric formed on a substrate (usually a silicon semiconductor substrate). Source and drain extension junctions are formed on opposing sides of the gate electrode by implanting N-type or P-type impurities into the substrate. Oxide or nitride spacers are normally formed adjacent to the gate prior to deeper source and drain implants.

A deep well is generally formed in the substrate to provide isolation and an electrical connection between the channel region of the transistor and a well contact. Ideally, the conductive path between the channel region and the well contact is characterized by low resistance to improve latch-up prevention and transistor substrate bounce. This is particularly more important as designs shrink.

Typically, creating a low resistance path between the channel region and the well contact has been done by increasing the dopant concentration in the well. This method involved performing a high-dosage well implant process prior to forming the transistor. However, increasing the dopant concentration causes the depletion region between the source/drain regions and the surrounding well area to become narrow, thereby increasing the junction capacitance between the source/drain regions and the surrounding well area. Because the delay of the transistor is proportional to the capacitance, the delay also increases.

For the dopant concentration needed at the peak of the well implant, the level of dopant at the bottom of the S/D junction is very high after implant. As such, even diffusion-less annealing or the co-implantation of other species to reduce diffusion will not enable lower dopant levels at the junction.

Therefore, what is needed is a method to reduce the junction capacitance while maintaining good conductivity between the channel region and the well contact.

### SUMMARY OF THE INVENTION

These and other problems are generally reduced, solved or circumvented, and technical advantages are generally achieved, by embodiments of the present invention, which provides a buried well for semiconductor devices.

In accordance with an embodiment of the present invention, a substrate having a buried well is provided. The substrate comprises a surface well formed on a first substrate and an epitaxial layer subsequently formed thereon. After forming the epitaxial layer, the surface well becomes a buried well. Because the epitaxial layer is formed after the surface well is formed, the epitaxial layer remains substantially undoped, creating a sharp increase in dopant concentration between the epitaxial layer and the buried well.

In an embodiment, a transistor is formed on the epitaxial layer. In this embodiment a portion of the epitaxial layer positioned between source/drain regions of the transistor and the buried layer may remain undoped, thereby creating a wide depletion region and low junction capacitance.

In another embodiment, the epitaxial layer may be doped to lower the resistance between the channel region of the transistor and a well contact.

In yet another embodiment, a channel implant may be performed in the channel region. In this embodiment, the channel implant extends from a surface of the epitaxial layer to the buried well under the gate electrode of the transistor, but regions of the epitaxial layer between the source/drain regions of the transistor and the buried well remain substantially undoped. The channel implant allows a low resistance path between the channel region and a well contact, while the undoped regions of the epitaxial layer reduce the junction capacitance.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The object and other advantages of this invention are best described in the preferred embodiment with reference to the attached drawings that include:

FIGS. 1, 2, and 3 illustrate cross-sections of a wafer after various process steps have been performed to fabricate a semiconductor device having a buried well in accordance with an embodiment of the present invention;

FIG. 1a is a graph illustrating a doping profile that may be used to form a buried well in accordance with an embodiment of the present invention; and

FIGS. 4-5 illustrate cross-sections of a wafer after various process steps have been performed to fabricate a semiconductor device having a buried well in accordance with another embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

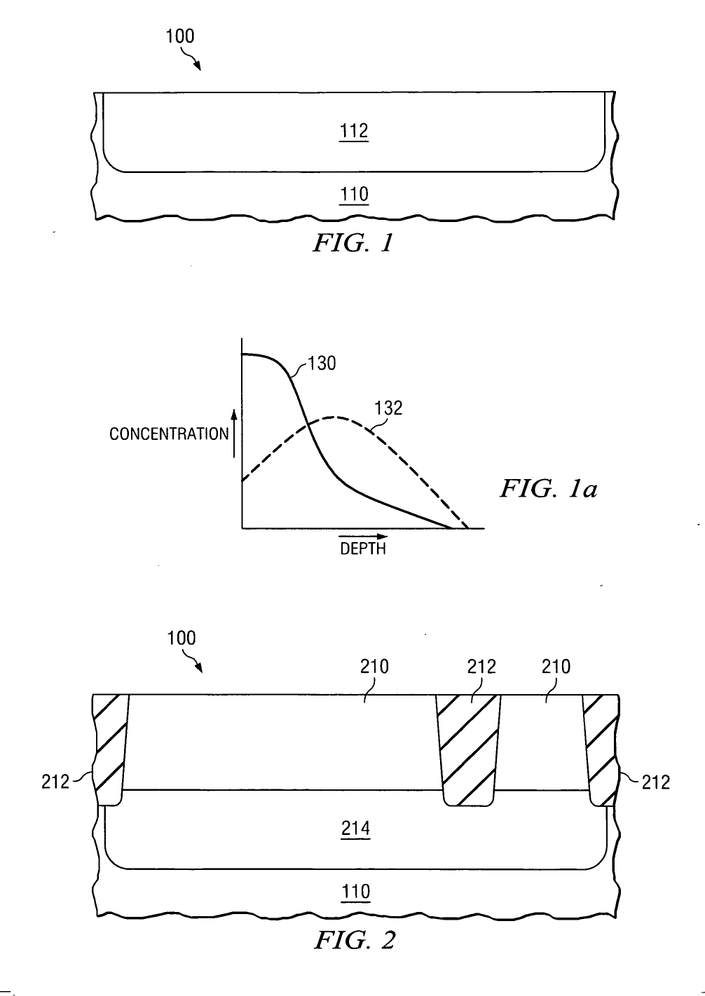

FIGS. 1-3 illustrate various stages of fabricating a MOS device utilizing a substrate having a buried well formed in accordance with an embodiment of the present invention. It should be noted that embodiments of the present invention are discussed in terms of forming an MOS transistor on a substrate having a buried well formed in accordance with an embodiment of the present invention for illustrative purposes only, and accordingly, embodiments of the present invention may be used to fabricate other types of devices, such as capacitors, diodes, resistors, bipolar transistors, or the like.

It should also be noted that the following method is equally applicable to NMOS and PMOS devices and that the dopants and processes discussed herein are provided for illustrative purposes only to better explain the present invention. Furthermore, embodiments of the present invention may be used in a variety of circuits, such as memory devices, logic devices, I/O devices, low or high voltage devices, and the like.

Referring first to FIG. 1, a wafer 100 is shown having a substrate 110 and a surface well 112 formed thereon. In an embodiment, the substrate 110 comprises a bulk silicon substrate. Other materials, such as germanium, silicon-germanium alloy, or the like, could alternatively be used for the substrate 110. Additionally, the substrate 110 may be a semiconductor-on-insulator (SOI) substrate, a silicon-on-sapphire substrate (SOS), or a multi-layered structure, such as a silicon-germanium layer formed on a bulk silicon layer.

The surface well 112 is formed in a top region of the substrate 110 and may be formed by implanting dopants into the top surface of the substrate 110. Preferably, the surface well 112 is of the same conductivity type as a deep well for a specific type of device. For example, a P-type surface well implant may be formed for use with an NMOS device by implanting boron ions, and an N-type surface well implant may be formed for use with a PMOS device by implanting phosphorous ions. In an embodiment the surface well implants are formed using a dose of about 1e12 to about 1e14 atoms/cm² with an energy such that the dopants are confined to a depth up to about 500 nm.

FIG. 1a, depicts a doping profile that may be used in an embodiment of the present invention. As illustrated, this embodiment utilizes two implants, preferably concentrating dopants along the surface of the substrate 110 and tapering off below the surface. However, it should be noted that the above dopant profile is provided for illustrative purposes only, and that other dopants and dopant profiles may be used. For example, a single implant or three or more implants may be used to create different doping profiles, and other N/P-type dopants, energy levels, and doses may be used.

Referring back to FIG. 1a, two implants are illustrated in this embodiment to achieve the desired slope of the dopant concentration. The first implant concentrates ions at the surface of the substrate 110 as illustrated by the doping profile labeled with reference numeral 130 in FIG. 1a. As illustrated by reference numeral 132 of FIG. 1a, the second implant concentrates dopants below the surface of the substrate. The combination of the first and second implants results in a dopant concentration that is high at the surface and generally decreases as depth of the substrate 110 increases.

Referring back to FIG. 1, it should be noted that one or more masking layers (not shown) may be used to selectively form the surface well 112 in the substrate 110. One skilled in the art will appreciate that separate implants may be used for NMOS and PMOS devices, thereby allowing both PMOS and NMOS devices may be formed on a single substrate.

Preferably, a rapid thermal anneal (RTA) is performed to repair damage done to the surface of the substrate 110 by the implant process. In an embodiment, it has been found that an RTA performed at a temperature of 1100° C. for 10 seconds, however this can also be done between about 700° C. to about 1100° C. for up to 30 minutes, repairs the surface of the substrate 110, thereby creating a smoother surface from which a layer may be grown in subsequent steps. By starting with a smoother surface, the subsequent layer may be more uniform and with fewer defects.

FIG. 2 illustrates the wafer 100 after a semiconductor layer 210 and shallow-trench isolations (STIs) 212 have been formed in accordance with an embodiment of the present invention. In an embodiment, the semiconductor layer 210 is a blanket epitaxially-grown layer wherein the substrate 110 acts as a seed crystal as is known in the art. Because the semiconductor layer 210 is grown prior to the formation of other structures, the semiconductor layer 210 may be grown as a wafer-wide blanket layer, i.e., it is not necessary to selectively grow the epitaxial layer. In this manner, the epitaxial layer may be grown more efficiently and without additional masking steps. The semiconductor layer 210 preferably has a thickness of about 100 nm to 300 nm, but more preferably about 200 nm to 300 nm.

The semiconductor layer 210 provides a substantially undoped semiconductor layer 210 in which NMOS and PMOS devices (e.g., transistors) may be formed. Thus, the surface well 112 of FIG. 1 becomes a buried well 214 in FIG. 2. As one of ordinary skill in the art will appreciate, embodiments of the present invention may be used to create a buried well having a high dopant concentration wherein the semiconductor material above the buried well has little or no dopant. Furthermore, the concentration of dopant in the buried well 214 can be independently determined without adversely affecting the performance of CMOS devices formed in the semiconductor layer 210. As will be discussed in greater detail below, this allows NMOS/PMOS devices to be formed on the wafer such that the dopant concentration in the depletion region is limited, thereby reducing the capacitance of the NMOS/PMOS device.

STIs 212, or some other isolation structures such as field oxide regions or deep trench isolation, are formed in the substrate 110 to isolate active areas on the substrate. The STIs 212 may be formed by etching trenches in the substrate and filling the trenches with a dielectric material, such as silicon dioxide, a high-density plasma (HDP) oxide, or the like. Preferably, the STIs 212 extend through the semiconductor layer 210 over the buried well 214 and contact the buried well 214.

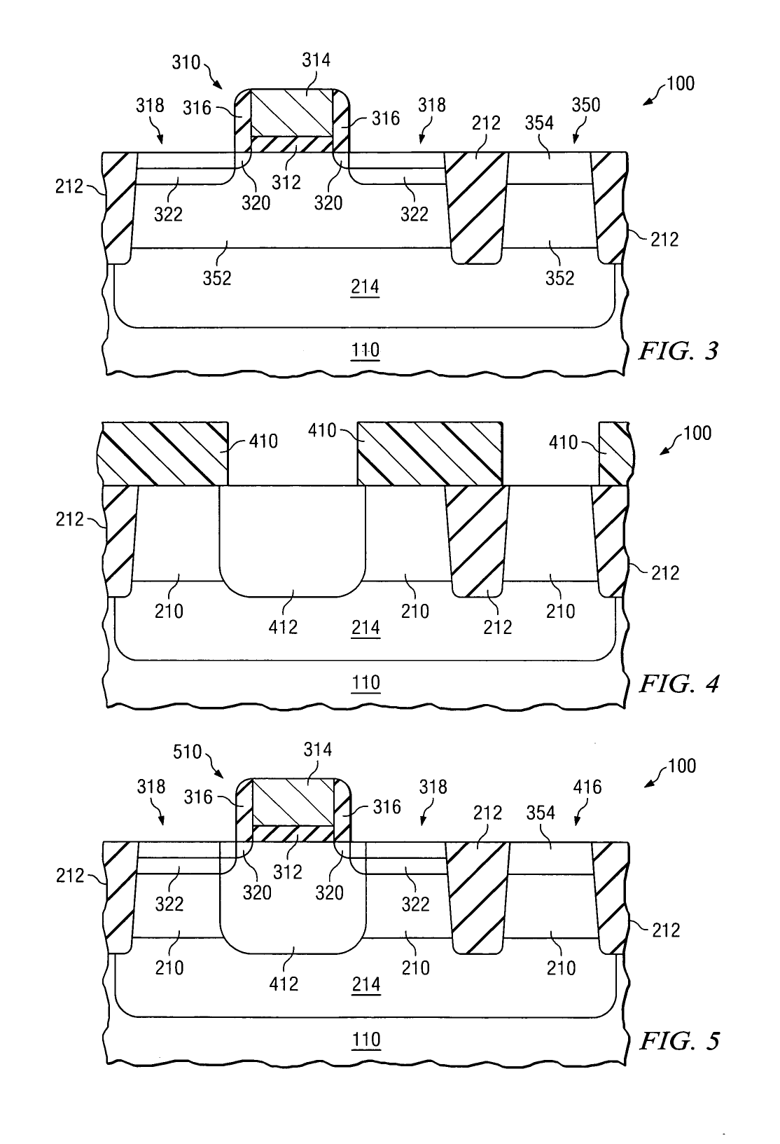

FIG. 3 illustrates the wafer 100 of FIG. 2 after a transistor 310 has been formed thereon. Generally, the transistor 310 comprises a gate dielectric 312, a gate electrode 314, spacers 316, and source/drain regions 318. The gate dielectric 312 comprises a dielectric material, such as silicon dioxide, silicon oxynitride, silicon nitride, a nitrogen-containing oxide, a high-K metal oxide, a combination thereof, or the like. A silicon dioxide dielectric layer may be formed, for example, by an oxidation process, such as wet or dry thermal oxidation. Other processes, materials, and thicknesses may be used.

The gate electrode 314 comprises a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, a combination thereof, or the like. In one example, amorphous silicon is deposited and re-crystallized to create poly-crystalline silicon (polysilicon). The polysilicon layer may be formed by depositing doped or undoped polysilicon by low-pressure chemical vapor deposition (LPCVD).

Spacers 316 may be formed by depositing and patterning a dielectric layer. In an embodiment the spacers 316 are formed by depositing, for example, silicon nitride and performing an isotropic or anisotropic etch process to form the spacers 316 as illustrated in FIG. 3. The spacers 316 may include multiple spacers and/or liners to create other doping profiles as desired for a particular application.

The source/drain regions 318 are shown as comprising a lightly-doped drain (LDD) 320 and a heavily-doped region 322 for illustrative purposes. The transistor may include, for example, halo implants and/or pocket implants.

A well contact 350 having a lightly-doped region 352 and a heavily doped region 354 may also be formed as is known in the art. Generally, the well contact 350 provides an electrical contact to the substrate and the channel region and is typically used to reduce the capacitance of the substrate below the gate electrode and the source/drain regions. The well contact 350 may be formed by performing a P⁻ or N⁻ implant that extends substantially to the buried well 214, thereby forming the lightly-doped region 352. A P⁺ or N⁺ implant may then be performed to form the heavily doped region 354. As one of ordinary skill in the art will appreciate, the lightly-doped region 352 and heavily-doped region 354 are typically doped with N-type ions to form a PMOS transistor and doped with P-type ions to form an NMOS transistor.

In the embodiment discussed above, the semiconductor layer 210 below the source/drain regions 318 and the gate electrode 314 are substantially undoped. Accordingly, the depletion region is wide creating a low capacitance junction. However, the semiconductor layer 210 below the gate electrode 314 is also substantially undoped. This undoped region below the gate electrode 314 is generally characterized by high resistance and may reduce the ability of the hot carriers to be conducted to the well contact in some applications.

In an alternative embodiment, the semiconductor layer 210 may be lightly doped (N-/P-type) to achieve greater conductivity between the channel region of the transistor 310 and the well contact 350. This greater conductivity will reduce the hot carrier charges and may be more desirable in some applications. In an embodiment, the semiconductor layer 210 may be doped by implanting an N-type dopant for a PMOS device or a P-type dopant for an NMOS device. In an embodiment, a lightly-doped well is formed such that a peak dopant concentration is at a depth from about 200 nm to about 300 nm. Other depths and/or doping profiles may be used.

FIGS. 4-5 illustrate yet another embodiment of the present invention in which dopants are implanted in a channel region to provide better conductivity between the channel region and the well contact. Referring first to FIG. 4, the wafer 100 of FIG. 2 (wherein like reference numerals refer to like elements) is shown after a mask 410 has been formed in accordance with an embodiment of the present invention. The mask 410 may comprise a photoresist material that has been deposited and patterned by known lithography techniques to expose a portion of the wafer 100 that is to become the channel region of a transistor. As illustrated in FIG. 4, the mask 410 may also be patterned to expose a well contact 416.

After patterning the mask 410, one or more implants may be performed to dope the well contact region 416 and a channel implant region 412. The channel implant region 412 and the well contact region 416 may be doped by performing a P⁻ or N⁻ implant such that the doped regions extend to the buried well and having a peak concentration below the source/drain regions.

Thereafter, a transistor 510 may be formed as described above with reference to the transistor 310 of FIG. 3, wherein like reference numerals refer to like elements. The heavily doped region 354 of the well contact 416 may also be formed.

As one of ordinary skill in the art will appreciate, this embodiment provides a lower resistance path between the channel region and the well contact 416 by doping the channel region down to the buried well 214, which electrically connects the channel region to the well contact 416. At the same time, the region below the source/drain regions 318 remains relatively undoped. As a result, the depletion region is wide and the junction capacitance between the source/drain regions and the surrounding well area is reduced.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a semiconductor device, the method comprising:
providing a semiconductor substrate;
performing one or more implants in a surface well;
forming a semiconductor layer on the surface well, the surface well becoming a buried well; and
forming an isolation structure in the semiconductor layer, the isolation structure extending through the semiconductor layer and contacting the buried well.

2. The method of claim 1, wherein the performing one or more implants concentrates ions at a surface of the semiconductor substrate.

3. The method of claim 1, further comprising annealing the semiconductor substrate after performing one or more implants and prior to forming the semiconductor layer.

4. The method of claim 1, further comprising forming a well contact in the semiconductor layer, the well contact comprising a doped region of the semiconductor layer extending through to the buried well.

5. The method of claim 1, further comprising:
forming a channel implant comprising a doped region of the semiconductor layer extending from a surface of the semiconductor layer to the buried well; and
forming a transistor on the semiconductor layer such that a gate electrode of the transistor overlies the channel implant.

6. The method of claim 5, wherein portions of the semiconductor layer positioned below source/drain regions of the transistor are substantially un-doped.

7. The method of claim 1, further comprising doping the semiconductor layer prior to forming a transistor on the semiconductor layer.

8. A method of forming a semiconductor device, the method comprising:
forming a well in a semiconductor substrate;
growing an epitaxial layer on the semiconductor substrate;
forming an isolation structure in the epitaxial layer, thereby defining a first region and a second region, the isolation structure extending through the epitaxial layer to the semiconductor substrate;
forming a transistor in the first region, the first region being positioned above the well; and
forming a well contact in the second region, the well contact extending through the epitaxial layer to the semiconductor substrate and being positioned over the well.

9. The method of claim 8, wherein the forming the well includes performing one or more implants concentrating ions at a surface of the semiconductor substrate.

10. The method of claim 8, further comprising annealing the semiconductor substrate after the forming the well and prior to the growing the epitaxial layer.

11. The method of claim 8, further comprising forming a channel implant below a gate electrode of the transistor prior to forming the transistor, the channel implant comprising a doped region of the epitaxial layer extending from the surface of the epitaxial layer to the well.

12. The method of claim 11, wherein portions of the epitaxial layer positioned below source/drain regions of the transistor are un-doped.

13. The method of claim 8, further comprising doping the epitaxial layer prior to forming the transistor.

14. A method of forming a semiconductor device, the method comprising:
providing a semiconductor substrate;
forming a surface well in a top region of the semiconductor substrate by implanting ions of a first conductivity type;
growing an epitaxial layer on the semiconductor substrate, the surface well becoming a buried well;
forming at least three isolation regions in the epitaxial layer, the isolation regions defining a first region and a well contact region and contacting the semiconductor substrate;
forming a transistor in the first region; and
doping the epitaxial layer in the well contact region.

15. The method of claim 14, wherein the forming the surface well concentrates ions at a surface of the semiconductor substrate.

16. The method of claim 14, further comprising annealing the semiconductor substrate after the forming the surface well and prior to the growing the epitaxial layer.

17. The method of claim 14, further comprising forming a channel implant below a gate electrode of the transistor prior to forming the transistor, the channel implant comprising a doped region of the epitaxial layer extending from the surface of the epitaxial layer to the buried well.

18. The method of claim 14, further comprising doping the epitaxial layer prior to forming the transistor.

19. A semiconductor device comprising:
a buried well formed in a semiconductor substrate;
an epitaxial layer overlying the buried well;
a transistor formed on the epitaxial layer;
an isolation structure formed through the epitaxial layer to the buried well, the isolation structure separating the transistor from other areas of the epitaxial layer; and
a channel implant region under a gate electrode of the transistor, the channel implant region extending from a surface of the semiconductor substrate to the buried well, wherein a region of the semiconductor substrate positioned between source/drain regions of the transistor and the buried well is undoped.

20. The semiconductor device of claim 19, wherein the buried well has ions concentrated at a surface of the semiconductor substrate.

21. The semiconductor device of claim 19, further comprising a well contact, the well contact being a doped region of the semiconductor substrate extending from the surface of the semiconductor substrate to the buried well.

22. The semiconductor device of claim 21, wherein the isolation structure is between the transistor and the well contact.
